(19) United States
(12) Patent Application Publication
(10) Pub. No.: US 2009/0162695 A1
(43) Pub. Date: Jun. 25, 2009

(54) SUBSTRATE WITH ANTIMICROBIAL PROPERTIES AND PROCESS FOR OBTAINING SUCH SUBSTRATE

(75) Inventors: Kadosa Hevesi, Jumet (BE); Florent Scarso, Jumet (BE)

Correspondence Address: OBLON, SPIVAK, MCCLELLAND MAIER & NEUSTADT, P.C., 1940 DUKE STREET, ALEXANDRIA, VA, 22314, US

(73) Assignee: AGC Flat Glass Europe S.A., Bruxelles (BE)

(21) Appl. No.: 12/339,213

(22) Filed: Dec. 19, 2008

Related U.S. Application Data
(63) Continuation of application No. PCT/EP2007/056109, filed on Jun. 20, 2007.

(30) Foreign Application Priority Data
Jun. 21, 2006 (EP) 06115786.3

(51) Int. Cl. B32B 9/00; C23C 14/34

(52) U.S. Cl. 428/698; 204/192.15; 428/688; 428/702

(57) ABSTRACT

A process for the production of a substrate having antimicrobial properties, including depositing a mixed layer on a substrate by sputtering under vacuum, the mixed layer containing at least one antimicrobial agent and a binder material selected from metal oxides, oxynitrides, oxycarbides, carbides, diamond like carbon and nitrides, where mixed targets are used for depositing the mixed layer. Substrates with mixed layers. Substrates made by the invention processes.

### REFERENCE TO PRIOR APPLICATIONS

The present application is a continuation of PCT/EP2007/056109, filed Jun. 20, 2007, and claims priority to EP 06115786.3, filed Jun. 21, 2006, both incorporated herein by reference.

### SUMMARY OF THE INVENTION

The present invention relates to a substrate of any type: metal, glass, glass ceramic, or plastic type substrate, for example, wherein at least one of its surfaces has antimicrobial, in particular antibacterial, anti-algal or antifungal properties. The present invention also relates to processes for the production of such a substrate.

### DISCUSSION OF THE BACKGROUND

In the field of ceramic substrates, EP 653 161, for example, describes the possibility of covering these with a glaze composed of silver to provide them with antibacterial properties.

In the field of glass-type substrates, sol-gel type processes are known to provide an antimicrobial surface. These processes require a hardening stage of the sol-gel layer, which involves elevated temperatures in the order of 500°-600° C. (sintering temperature). Processes are also known that require the substrate to be dipped in a composition comprising a silver salt. In this case, a silver layer is not deposited, but an ion exchange takes place in the solution at an elevated temperature.

A process for producing a glass substrate having antimicrobial properties is also known from EP 1449816. This process uses AgNO3 in oil and requires both a drying stage between 20° and 105° C. and a thermal treatment at 600-650° C. This thermal treatment has some disadvantages particularly with respect to cost and uniformity of the product. Moreover, it renders the process very poorly reproducible, since it has been found that at these temperatures the diffusion of the silver is very rapid and a slight variation in the duration of the thermal treatment results in a significant variation in the depth of diffusion of the silver, and therefore this causes variation in the antibacterial properties of the substrate.

In particular, we have observed that with such a process, the majority of the silver has diffused between around 1 and 2 μm and that at the surface the quantity of silver is too low to give antimicrobial properties to the glass.

It may also be noted that such a thermal treatment causes an undesirable yellow colouration of a soda-lime glass substrate. Furthermore, if the thermal treatment is carried out during a tempering process, after having been treated, the product may no more be cut into particular size.

WO 95/13704 describes antimicrobial coatings deposited on medical devices. The coatings have been designed to present atomic disorder in the materials, the main purpose being to provide sustained release of antimicrobial agents, in particular silver, when in contact with an alcohol or electrolyte.

In example 9, separated layers of Ag and ZnO were deposited sequentially by RF magnetron sputtering in a ratio of 75-25 wt %. The total thickness of the layers is 330 nm. RF magnetron sputtering is a deposition method which is hardly industrially useful today.

Therefore, there is a need to provide a substrate, either glass or metallic, with antimicrobial properties, which is easy to use and inexpensive to produce in an industrial manner.

To reply to this need, a process has now been discovered to produce layers on a substrate in which one or more anti-microbial agent are mixed in a matrix material.

### DETAILED DESCRIPTION OF THE PREFERRED EMBODIMENTS

In particular, there is a need to provide a glass substrate which can be tempered and which keeps antimicrobial properties, preferably bactericide properties, after tempering process, although the invention is not limited to a particular type of substrate.

In particular, one aim of the invention is to provide a glass substrate which can be tempered and which keeps antimicrobial properties after accelerating ageing tests carried out after tempering process.

It has been found that it is possible to deposit the mineral layer and the antimicrobial agent in one single step over the entire substrate, whether it is made of metal, e.g. steel, or is a glass-type substrate, etc.

According to one embodiment, the present invention relates to a process for the production of a substrate having antimicrobial properties, characterised in that it comprises depositing a mixed layer comprising at least one antimicrobial agent mixed with a binder material chosen amongst metal oxides, oxynitrides, oxycarbides, carbides, DLC or nitrides by sputtering under vacuum, wherein mixed targets are used for depositing said mixed layer.

Particular mixed layers comprise, consist essentially of, or consist of a layer of Ag doped SiO2, SnO2, ZrO2, ZnO, TiO2, NbOx, Al2O3, NiCrOx, Si3N4, TiN, AlN or mixtures thereof, in particular ZnxSnyOz, TiZrOx or SiOxNy. As is well known to those of ordinary skill in this art, the values of x and y, etc in such compounds can vary widely depending on the targets used, deposition conditions used, etc., all of which are within the normal and ordinary control of those who would use this invention.

With the well known method of magnetron sputtering, it is possible to form a doped layer, e.g. of a metal oxide doped with another materials, two different metal targets are generally used in the same deposition chamber (co-sputtering).

In magnetron sputtering, the nature of the materials in the targets can be different from the deposited materials (for example, metals in the target can become metal oxides or metal nitrides in the deposited layer; suboxidised ceramics in the target can become oxides in the layer, etc . . . ). In the present invention, the targets are mixtures of several materials that will play two different roles in the deposited mixed layer, eventually after a change of chemical nature due to the sputtering process: some materials will act as antimicrobial agents while other(s) will act as the matrix material. The invention process includes using targets made up of a mixture of one or more antimicrobial agent, in any chemical form, in particular in metal or metal oxide form, with one or more materials that will become the binder material in the deposited mixed layer. The total weight percentage of the antibacterial agents in the targets is not limited, but is advantageously less than 50%, preferably less than 25% and further preferred less than 15%.

For example, Ag, Cu, Au and Zn can be mixed with oxides of Ti, NiCr, Zr and other pure or mixed oxides in order to produce mixed ceramic-based targets which lead to highly efficient processes in terms of deposition rate and process stability.

It has also been found that a wide range of magnetron sputtering processes can be used to obtain the desired antimicrobial coating. DC (direct current) power as well as mid-frequency pulsed DC (frequency between 0.1 and 500 kHz) or AC (alternative current) power has been used successfully in sputtering mixed targets.

According to one embodiment, the process according to the invention uses DC or unipolar pulsed powering and one single mixed target is used in each deposition chamber.

According to another embodiment, the process uses AC or bipolar powering and two mixed target are used in each deposition chamber.

Gas mixtures including Ar, O2 and N2 can been used over the whole range of 0 to 100% for each gas, depending on the type of material desired for the layer comprising the antimicrobial agent.

With these processes, no additional or subsequent diffusion of the antimicrobial agent may be needed. We obtain an antimicrobial substrate in one step, without any thermal treatment, which is cost saving.

It has also been discovered that, if a tempered and antimicrobial glass is required, a sputtering process may be used, and optionally an underlayer may be added. Antimicrobial (in particular bacteriostatic but also bactericidal) properties may be maintained even after a tempering process (implying high temperature treatment during approximatively 2 to 10 min).

Layers of Ag doped metal oxide deposited in a single step by co-sputtering or sputtering of mixed targets, have been made which have antimicrobial properties with a simple process that does not require any thermal treatment.

The coated substrate obtained according to the claimed process may comprise at least one mineral binder material, particularly selected from metal oxides, oxynitrides, oxycarbides, carbides, DLC (diamond like carbon) or nitrides, mixed with at least one antimicrobial agent. It generally maintains antimicrobial properties after accelerated ageing tests. In particular, the mineral binder material can be selected from oxides of silicon, tin, nickel, chrome, zinc, titanium, niobium, aluminium, zirconium or mixtures thereof, for example ZnxSnyOz and NiCrOx. Particularly preferred nitrides are silicon, titanium and aluminium nitrides and mixtures thereof.

The antimicrobial agent can be selected from various inorganic agents known for their antimicrobial properties, in particular silver, copper, gold and zinc, or mixture thereof. Advantageously, the antimicrobial agent is in ionic form.

By antimicrobial properties it is meant anti-bacterial properties but also anti-fungal or anti-algal properties.

The mixed layer comprising the antimicrobial agent has advantageously a thickness greater than 2 nm, preferably greater than 5 nm and particularly preferred greater than 8 nm and lower than 300 nm, preferably lower than 250 nm, and particularly preferred lower than 200 nm.

The substrate can be metallic, e.g. made of steel, or stainless steel or ceramic type or plastic or thermoplastic type substrate or a glass-type substrate, in particular a sheet of flat glass, particularly soda-lime glass which may be float glass. It may be clear glass or coloured glass. Frosted or patterned glass can also be used. The glass sheets can be treated on one or on both of their faces. The face opposite the treated face can be subjected to any desired type of surface treatment. It may comprise a reflective layer (to form a mirror) or a layer of enamel or painting (for wall covering), generally at the surface opposite to the antimicrobial surface.

The substrate may for example have a thickness within the range of 0.2 to 12 mm.

The substrate may for example have a surface area of greater than 0.8 m to 0.8 m; it may be adapted to be cut to a finished size by a subsequent cutting operation.

It is conceivable that the antimicrobial glass substrate thus obtained is subjected to a thermal treatment stage such as, in the case of glass substrate, a thermal tempering, bending or hardening, while still retaining its antimicrobial properties.

In some embodiments of the invention, a substrate having antimicrobial agents present at least at one exposed surface may be a sheet of annealed glass. The term annealed sheet of glass is used herein to mean that the glass may be cut to size without breaking in the way that a tempered or hardened sheet of glass would break upon cutting. Such a sheet of annealed glass preferably has a surface compression of less than 5 MPa. After the eventual cutting operation, the substrate is able to be tempered and antimicrobial properties are maintained.

In an advantageous embodiment of the invention, the substrate can be first coated with an underlayer that blocks or slows down the diffusion of the antimicrobial agents, in particular during the tempering treatment. The function of the underlayer can be ascertained on a product made according to the invention by comparing the antimicrobial effect of similar products with and without undercoating and/or by analysing diffusion profiles.

In particular, the blocking underlayer may be chosen amongst pyrolitic and sputtered layers, in particular layers comprising metal oxide, metal oxinitride, metal or metal alloy compound, such as Pd, Ni, Cr, Y, TiOx, NiCrOx, Nb, Ta, Al, Zr or ZnAl, SnO2, ZnxSnyOz, SiOx, SiOxNy, ZrOx or any mixtures thereof. TiZrOx is a particularly preferred underlayer.

The blocking underlayer may also be chosen amongst metal nitride, in particular nitride of Si, Ti, Zr or Al or mixtures thereof.

In the case of metallic substrates, particularly preferred undercoat and/or mixed layers are chosen amongst titanium oxide, titanium nitride, zirconium oxide, silicon oxide or silicon oxinitride.

Advantageously, the underlayer has a thickness greater than 1 nm, preferably greater than 10 nm and particularly preferred greater than 50 nm.

The substrate according to the invention preferably has an antibacterial effect on a large number of bacteria, whether gram positive or gram negative bacteria, in particular on at least one of the following bacteria: Escherichia coli, Staphylococcus aureus, Pseudomonas aeruginosa, Enterococcus hirae. The antibacterial effect, measured in accordance with the JIS Z 2801 standard, is in particular, at least on any one of these bacteria, higher than log 1, preferably higher than log 2 and particularly preferred higher than log 2.5. The substrate will be considered bactericidal according to the JIS Z 2810 standard if it has an effect higher than log 2. However, the invention also relates to substrates that have a lower effect (for example bacteriostatic effect, which means that the bacteria are not necessarily killed but can not develop any more).

When the substrate used is a clear glass, it can advantageously have antimicrobial properties as well as a neutral colouration in reflection. In particular, the calorimetric indexes (CIELAB system) in reflection a* and b* (Illuminant C, 10° observer) may be in the range of between −10 and 6, preferably between −8 and 3 and particularly preferred between −6 and 0, and the purity may be less than 15%, preferably less than 10% and particularly preferred less than 5%. If an underlayer is deposited a slight absorption in the visible (around 5 to 25%) may be imparted to the underlayer. It may have a visible light reflection around 8 and 15%,

If the substrate is a coloured glass, antimicrobial properties may be obtained without changing very much the initial colour of the substrate. The change of coloration is generally expressed with the colorimetric index by Delta E*; Delta E*=[(L*1-L*2)2+(a*1-a*2)2+(b*1-b*2)2]½. A Delta E* lower than 3, preferably lower than 2 may be obtained for an antimicrobial substrate according to the invention.

When the substrate is transparent (glass, plastic, . . . ), it may be advantageous to obtain antimicrobial properties while keeping the substrate essentially transparent. In particular, with a clear soda-lime glass of 4 mm, the average light transmission in the visible range of the coated substrate according to the invention may be higher than 50%, preferably higher than 60% and most preferably higher than 65%.

When the glass substrate used is a clear glass, it may advantageously have both antimicrobial properties and a low visible light absorption.

The substrate according to the invention has an antimicrobial effect after at least one of the following accelerated ageing tests: wet spray test (test over 20 days in a chamber with a humidity of more than 95% at 40° C.), after 500 hours of UV irradiation (4 340A ATLAS lamps, chamber at 60° C.), after 24 hours immersed in a solution of H2SO4 (0.1 N), after 24 hours immersed in a solution of NaOH (0.1 N), 48 hours of immersion in Mr Propre® detergent followed by 5 days of drying.

It may be advantageous to use an undercoat comprising an oxide of zirconium. This may particularly be so when the mixed layer comprises an antibacterial agent and an oxide of titanium, particularly a titanium oxide in its anatase crystallised form.

Additional or alternative embodiments of the present invention are also described in dependant claims.

The present invention shall be described in more details below, in a non-restrictive manner:

### EXAMPLE 1 (COMPARATIVE)

One sample of clear soda-lime glass having a thickness of 4 mm was coated with a layer of SiO2(Al):Ag by co-sputtering. Two metal targets were used in a mixed atmosphere of argon and oxygen: one was composed of silicon doped with 8% Al and the second target was a metallic silver target. The Si(Al) target was sputtered with a pulsed DC power supply at 100 kHz while the Ag target was sputtered with DC power supply. The electric power supplies were regulated in order to obtain 10 mg of Ag in the layer per square meter of substrate with the total layer thickness of 24 nm.

Measurement of the Antimicrobial Effect The bactericidal properties (in particular on E. Coli) of all the samples were analysed in accordance with standard JIS Z 2801. A log 1 level indicates that 90% of the bacteria inoculated onto the surface of the glass were killed in 24 hours in the conditions of the standard; log 2 indicates that 99% of the bacteria were killed; log 3 indicates that 99.9% of the bacteria deposited were killed etc. If the value indicated is greater than a particular amount, this mean that the maximum of countable bacteria was killed.

A value greater than log 4 was obtained before tempering the sample.

Tempering Treatment

The coated sample was subjected to a common tempering treatment (670° C. during 200 sec.). And the bactericidal properties were analysed in same way as for the sample before tempering step. A log 0.76 was obtained which means that no bactericidal nor bacteriostatic properties were maintained after tempering the coated glass.

### EXAMPLES 2 AND 3

Samples of the same clear soda-lime glass (4 mm thick) were first coated with an underlayer and then coated with a layer of 24 nm of SiO2—Ag by co-sputtering using the same conditions as in example 1. The electric power supplies were regulated in order to obtain 20 mg/m2 of Ag in the layer.

In example 2, the underlayer is a double underlayer deposited by CVD (Chemical Vapor Deposition) consisting of 75 nm of SiOxCy and 320 nm of fluorine doped tin oxide, the surface being slightly polished after deposition.

In example 3, the underlayer is also a double SiOxCy/SnO2:F layer but not polished.

The antibacterial effect was measured in the same manner as in example 1. Values greater than log 4 were obtained.

After a tempering treatment carried out in the same manner as in example 1, antibacterial values greater than log 4 were maintained.

Accelerated Ageing Tests

The following ageing tests were carried out:
wet spray (test for 20 days in a chamber with a humidity of more than 95% and at 40° C.);
500 hours of UV irradiation (4 340A ATLAS lamps, chamber at 60° C.),
24 hours of immersion in an H2SO4 solution (0.1 N),
48 hours of immersion in Mr Propre® “salle de bain liquide” detergent followed by 5 days of drying.

The antibacterial properties were again measured on the samples having been tempered and then subjected to the accelerated ageing tests.

The sample of example 2 maintained a log 4.9 value after H2SO4 immersion, a log 4.7 value after the wet spray test, a log 4.1 after the detergent immersion test and after the UV test.

The sample of example 3 maintained a log 4.5 value after H2SO4 immersion, a log 4.7 value after the wet spray test, a log 3.6 after the detergent immersion test and a log 4.1 after the UV test.

### EXAMPLE 4

Samples of the same clear soda-lime glass (4 mm thick) was first coated with a CVD underlayer of 75 nm of SiOxCy and 320 nm of fluorine doped tin oxide, and the surface has been slightly polished after deposition.

The samples have then been coated with a layer of 15 nm of SiO2—Ag by co-sputtering. As in example 1, two metal targets were used in a mixed atmosphere of argon and oxygen: one was composed of silicon doped with 8% Al and the second target was a metallic silver target. Both targets were sputtered with one single AC electric power supply operating at 27 kHz and being regulated in order to obtain 15 mg of Ag in the layer per square meter of substrate.

The antibacterial effect was measured in the same manner as in the other examples. Values greater than log 4 were obtained.

After the tempering treatment carried out in the same manner as in example 1, antibacterial value of log 4.6 was maintained.

The tempered samples were then subjected to accelerated ageing tests. After a wet spray test, the antibacterial properties were maintained to a value greater than log 4. After the detergent immersion test, a value of log 3.7 was obtained and after the UV test, a log 2.5 was obtained.

### EXAMPLE 5

Samples of the same clear soda-lime glass were first coated with the same double CVD underlayer as in examples 2 and 4. A layer of SiZrOx doped with Ag was then deposited by co-sputtering using two metallic targets (Si—Zr (10 wt % Zr) and Ag). Both targets were sputtered with one single electric power supply being regulated in order to obtain a total thickness of 19 nm and 21 mg/m2 of Ag.

The antibacterial effect was measured in the same manner as in the previous examples. On the samples before tempering (a value greater than log 4 was obtained), after tempering (a value greater than log 4.6 was obtained). The tempered samples were subjected to accelerating ageing tests. After the H2SO4 immersion test, a bactericidal value greater than log 4.9 was maintained. After the wet spray test, a value greater than log 4.7 was obtained and after the detergent immersion test, a log 4.1 was obtained.

### EXAMPLES 6 AND 7

Samples of the same clear soda-lime glass were first coated with the same double CVD underlayer as in examples 2 and 4. A layer of TiAlOx doped with Ag was then deposited by co-sputtering using one Ag metal target and one ceramic target TiAlOx (12 wt % AlOx) in a mixed atmosphere of argon and oxygen.

In example 6, the Ti(Al)Ox target was sputtered with a pulsed DC power supply at 100 kHz while the Ag target was sputtered with a DC power supply. The electric power supplies were regulated in order to obtain a thickness of 60 nm and 26 mg/m2 of Ag in the layer.

In example 7, both targets were sputtered with one single AC power supply regulated in order to obtain a thickness of 7 nm and 30 mg/m2 of Ag in the layer. The antibacterial effect was measured in the same manner as in the previous examples. On the sample before tempering a value greater than log 4 was obtained, after tempering a value greater than log 4.6 was obtained.

Good antibacterial properties were obtained for all examples of the invention before and after tempering treatment. Whereas in the comparative example 1 where no underlayer was deposited the antibacterial properties were no more observable when then sample has been tempered.

Each time an accelerating ageing test has been carried out, the sample according to the invention maintained good antibacterial properties.

Furthermore a sand abrasion test was carried out in order to measure the mechanical resistance of the coated samples. In this test, a piece of felt is rubbed on the sample for 600 passes. A weight of 1050 g is applied on the felt while an abrasive solution is poured on the sample (160 g of sand, mesh 500 per litre of water). After the test is completed, the change of reflected colour in the abraded zone is measured and expressed as delta E*.

For example 6, a delta E* of 2.2 was obtained, which means that the mechanical resistance of the layer is acceptable.

For example 7, a delta E* of 0.5 was obtained, which means that the change of colour is undetectable with the eyes and that the mechanical resistance of the layer is very good.

The antibacterial properties were measured also after the abrasion test. For example 6, same very good level of antibacterial activity was obtained. For example 7, a log 2.4 was obtained which means that the sample was still bactericidal.

### EXAMPLE 8

One sample of clear soda-lime glass having a thickness of 4 mm was coated with a layer of ZrO2:Ag by co-sputtering. Two metal targets were used in a mixed atmosphere of argon and oxygen: one was composed of zirconium and the second target was a metallic silver target. An unipolar pulsed electric power supply was used and was regulated in order to obtain 7 wt % of Ag in the layer. The layer thickness was 225 nm.

The bactericidal properties of the sample was analysed in accordance with Standard JIS Z 2801 before and after tempering process The coated sample was subjected to a tempering treatment (670° C. during 200 sec.). And the bactericidal properties were analysed. A log 3.8 was obtained which means that the sample has good bactericidal properties after tempering.

### EXAMPLES 9 AND 10

Samples of the same clear soda-lime glass (4 mm thick) was first coated with a CVD underlayer of 75 nm of SiOxCy and 320 nm of fluorine doped tin oxide, and the surface has been slightly polished after deposition as in the previous examples 2 and 4-7.

A layer of TiOx doped with Ag has been deposited by magnetron co-sputtering using one metal target of Ag and one ceramic target TiOx respectively in a mixed atmosphere of argon and oxygen for example 9 and in a atmosphere comprising mainly argon for example 10.

For both samples, the Ag target was sputtered with a pulsed DC power supply at 50 kHz with 50 μs one time, while the TiOx target was sputtered with DC power supply. The electric power supplies were regulated in order to obtain a layer of respectively 38 nm thick for example 9 and 11 nm for example 10. The layer comprises respectively 5 mg/m2 of Ag in example 9 and 4 mg/m2 of Ag in example 10.

The samples were tempered as in the previous examples and the H2SO4 and NaOH accelerated ageing tests described above were carried out. Antibacterial effect was measured in the same manner as described above.

For ex 9, values of log 2.4 and 1.9 were obtained respectively after H2SO4 test and NaOH test.

For ex 10, values of log 2.8 and 2.0 were obtained respectively after H2SO4 test and NaOH test.

After the sand abrasion test described in examples 6-7, the delta E* was respectively 0.9 (Ex 9), and lower than 0.5 (Ex. 10). This means that the mechanical resistance of the layer is very good.

### EXAMPLE 11

A sample of the same clear soda-lime glass was first coated with the same double CVD underlayer as in examples 2 and 4-7, 9-10. A layer of SiOxNy doped with Ag was then deposited by co-sputtering using one target of silicon and one target of silver in a mixed atmosphere of argon, nitrogen and oxygen.

The Si target was sputtered with a pulsed DC power supply at 50 kHz with 5 μs while the Ag target was sputtered with a DC power supply. The electric power supplies were regulated in order to obtain a layer of 12 nm with 1 mg/m2 of Ag.

A sand abrasion test was carried out as described hereinabove. The delta E* measured was 1.6 which means that the mechanical resistance of the layer is good.

### EXAMPLE 12

A sample of the same clear soda-lime glass (4 mm thick) was first coated with a CVD underlayer of 75 nm of SiOxCy and 320 nm of fluorine doped tin oxide, and the surface has been slightly polished after deposition as in the previous examples 2 and 4-7.

A layer of TiOx doped with Ag has been deposited by magnetron sputtering using a single target of mixed ceramic titanium and Ag (1.3 wt %). The single target was sputtered with a normal DC power supply in a mixed atmosphere of argon and oxygen. The electric power supply was regulated in order to obtain a layer of 36 nm with 2.2 mg/m2 of Ag.

Very good antibacterial properties were obtained after tempering and after sand abrasion test (log4.7).

The colour in reflection was measured on the coated side for most of the samples. The results are summarized in the following table. All the values are obtained according to the Cielab system (D65, 10°). The light transmission integrated on the visible wavelengths has also been measured from some samples in D65, 2°.

| | L* | a* | b* | Tv |
|---|---|---|---|---|
| Example 2 | 42.4 | −3.6 | 3.3 | |
| Example 4 | 42.7 | −6.5 | 1.5 | |
| Example 5 | 42.3 | −5.9 | 3.3 | |
| Example 6 | 42.6 | −5.2 | −1.0 | |
| Example 7 | 44.1 | −5.5 | 0.6 | |
| Example 9 | 57.4 | −0.6 | −4.4 | 67.7 |
| Example 10 | 45.3 | −5.3 | −1.7 | 77.9 |
| Example 11 | 43 | −6.9 | 0.7 | 81.8 |
| Example 12 | 58.1 | 3.3 | −5.0 | 80.4 |

For the ease of the manipulations, all the examples have been done with Ag as antimicrobial agent, but the same results are expected with Cu which is also known for his antimicrobial properties.

The above written description of the invention provides a manner and process of making and using it such that any person skilled in this art is enabled to make and use the same, this enablement being provided in particular for the subject matter of the appended claims, which make up a part of the original description and including the appended claims.

As used herein, the phrases “selected from the group consisting of” “chosen from,” and the like include mixtures of the specified materials. Terms such as “contain(s)” and the like as used herein are open terms meaning ‘including at least’ unless otherwise specifically noted.

All references, patents, applications, tests, standards, documents, publications, brochures, texts, articles, etc. mentioned herein are incorporated herein by reference. Where a numerical limit or range is stated, the endpoints are included. Also, all values and subranges within a numerical limit or range are specifically included as if explicitly written out.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein.

What is claimed is:

1. A process for the production of a substrate having antimicrobial properties, comprising depositing a mixed layer on a substrate by sputtering under vacuum, said mixed layer comprising at least one antimicrobial agent and a binder material selected from the group consisting of metal oxides, oxynitrides, oxycarbides, carbides, diamond-like carbon and nitrides, wherein mixed targets are used for depositing said mixed layer.

2. The process according to claim 1, wherein the mixed layer is deposited by sputtering under vacuum using DC powering, unipolar pulsed powering or bipolar powering, at a frequency of 0.1 to 500 kHz.

3. The process according to claim 1, wherein the mixed targets are a mixture of ceramic material as main material and metallic materials as doping material.

4. The process according to claim 1, wherein a mixed layer is deposited by sputtering under vacuum using a target which is a mixture of
one or more antibacterial agents, in a metallic form or a metal oxide form,
one or more materials to become the binder material in the deposited mixed layer.

5. The process according to claim 1, wherein the mixed layer is deposited by sputtering under vacuum using one single mixed target and using DC or unipolar pulsed powering at a frequency of 0.1 to 500 kHz.

6. The process according to claim 1, wherein the mixed layer is deposited by sputtering under vacuum using two mixed targets and using AC or bipolar powering at a frequency of 0.1 to 500 kHz.

7. The process according to claim 1, wherein the antimicrobial agent is selected from silver, copper, gold and zinc or mixture thereof.

8. The process according to claim 1, wherein the mixed layer consists of a layer of Ag doped SiO2, SnO2, ZrO2, ZnO, TiO2, NbOx, Al2O3, NiCrOx, Si3N4, TiN, AlN or mixture thereof.

9. The process according to claim 1, wherein the mixed layer consists of a layer of Ag doped ZnxSnyOz, Ti ZrOx or SiOxNy.

10. The process according to claim 1, wherein the mixed layer has a thickness greater than 2 nm and lower than 300 nm.

11. The process according to claim 3, wherein the mixed targets used are targets of mixed ceramic titanium and antimicrobial metallic material.

12. The process according to claim 1, wherein the mixed target is a target of mixed ceramic titanium and Ag.

13. The process according to claim 1, wherein the substrate is metallic.

14. The process according to claim 1, wherein the substrate is a glass substrate.

15. The process according to claim 1, wherein at least one underlayer is deposited on the substrate before the deposition of the mixed layer, wherein said underlayer slows down or blocking the diffusion of antimicrobial agents.

16. The process according to claim 14 wherein the underlayer is selected from the group consisting of pyrolitic and sputtered layers.

17. The process according to claim 14 wherein the underlayer comprises a metal oxide, metal or metal alloy compound selected from the group consisting of Pd, Ni, Cr, Y, TiOx, NiCrOx, Nb, Ta, Al, Zr, ZnAl, SnO2, ZnxSnyOz, SiOx, SiOxNy, and ZrOx or a metal nitride selected from the group consisting of nitrides of Si, Ti, Zr and Al and mixtures thereof.

18. The process according to claim 16 wherein the underlayer is deposited by CVD.

19. A process for the production of a substrate having antimicrobial properties, wherein an underlayer comprising ZrO2 is first deposited on the substrate; a mixed layer comprising at least one antimicrobial agent mixed with a binder material is then deposited on at least a part of the underlayer by sputtering under vacuum, using a mixed target of ceramic titanium and an antimicrobial agent.

20. A process for the production of a tempered and antimicrobial glass substrate, wherein a mixed layer comprising an antimicrobial agent and a binder material is deposited on the substrate by a sputtering vacuum process to form a coated substrate and the coated substrate is tempered at a temperature of 600 to 800° C. for 2 to 10 min.

21. The process according to claim 20, wherein at least one underlayer is deposited on the substrate before depositing the mixed layer, the underlayer blocking or slowing down the migration of the antimicrobial agent during the tempering step.

22. The process according to claim 20, wherein the underlayer is a metal nitride.

23. A substrate coated at least partially on at least one of its surfaces with at least one mixed layer comprising at least one antimicrobial agent and a binder material selected from the group consisting of metal oxides, oxynitrides, oxycarbides, carbides, diamond like carbon and nitrides.

24. A substrate according to claim 23, prepared by depositing a mixed layer on a substrate by sputtering under vacuum, said mixed layer comprising at least one antimicrobial agent and a binder material selected from the group consisting of metal oxides, oxynitrides, oxycarbides, carbides, diamond like carbon and nitrides, wherein mixed targets are used for depositing said mixed layer.
